(19) United States
(12) Patent Application Publication
(10) Pub. No.: US 2026/0334046 A1
(43) Pub. Date: Oct. 22, 2026

(54) DISPLAY PANEL AND ELECTRONIC APPARATUS INCLUDING THE SAME

(71) Applicant: Samsung Display Co., Ltd., Yongin-si (KR)

(72) Inventors: Sungjae Park, Yongin-si (KR); Jaebum Cho, Yongin-si (KR); Nayoung Kim, Yongin-si (KR); Daewook Kim, Yongin-si (KR); Kyusu Ahn, Yongin-si (KR); Jewon Yoo, Yongin-si (KR); Jongbeom Hong, Yongin-si (KR)

(21) Appl. No.: 19/578,140

(22) Filed: Mar. 25, 2026

(30) Foreign Application Priority Data
Apr. 21, 2025 (KR) 10-2025-0051826

(51) Int. Cl. H10K 59/80; H10K 59/38

(52) U.S. Cl. CPC H10K 59/80515; H10K 59/38

(57) ABSTRACT

A display panel includes a substrate, a first-1 pixel electrode disposed on the substrate and having an upper surface including a valley and a peak, each extending in a first-1 direction, and a first-2 pixel electrode disposed on the substrate and having an upper surface including a valley and a peak, each extending in a first-2 direction crossing the first-1 direction.

This application claims priority to Korean Patent Application No. 10-2025-0051826, filed on Apr. 21, 2025, and all the benefits accruing therefrom under 35 U.S.C. § 119, the content of which in its entirety is herein incorporated by reference.

### BACKGROUND

### 1. Field

Embodiments relate to a display panel and an electronic apparatus including the same, and more particularly, to a display panel capable of displaying high-quality images and an electronic apparatus including the display panel.

### 2. Description of the Related Art

Display panels have been used in various electronic apparatuses. When electronic apparatuses display images, it is desired to prevent or minimize the quality of images viewed by users from deteriorating due to external light.

### SUMMARY

However, in a display panel according to the related art and an electronic apparatus including the same, when there is a light source of relatively high brightness outside, the quality of images viewed by users rapidly deteriorates.

Embodiments include a display panel capable of displaying high-quality images, and an electronic apparatus including the display panel. However, such an objective is an example, and the scope of the disclosure is not limited thereto.

Additional features will be set forth in part in the description which follows and, in part, will be apparent from the description, or may be learned by practice of the presented embodiments of the disclosure.

In an embodiment of the disclosure, a display panel includes a substrate, a first-1 pixel electrode disposed on the substrate and having an upper surface including a first-1 valley and a first-1 peak, each extending in a first-1 direction, and a first-2 pixel electrode disposed on the substrate and having an upper surface including a first-2 valley and a first-2 peak, each extending in a first-2 direction crossing the first-1 direction.

In an embodiment, the first-1 pixel electrode and the first-2 pixel electrode may be arranged in sub-pixels emitting light of a same first color.

In an embodiment, the display panel may further include a second-1 pixel electrode disposed on the substrate and including an upper surface including a second-1 valley and a second-1 peak, each extending in a second-1 direction, and a second-2 pixel electrode disposed on the substrate and including an upper surface including a second-2 valley and a second-2 peak, each extending in a second-2 direction crossing the second-1 direction.

In an embodiment, the first-1 pixel electrode and the first-2 pixel electrode may be arranged in sub-pixels emitting light of a same first color, and the second-1 pixel electrode and the second-2 pixel electrode may be arranged in sub-pixels emitting light of a same second color.

In an embodiment, the first-1 pixel electrode and the second-1 pixel electrode may belong to a first pixel, the first-2 pixel electrode and the second-2 pixel electrode may belong to a second pixel, the first-1 direction and the second-1 direction may be parallel to each other, and the first-2 direction and the second-2 direction may be parallel to each other.

In an embodiment, the first-1 pixel electrode and the second-1 pixel electrode may belong to a first pixel, the first-2 pixel electrode and the second-2 pixel electrode may belong to a second pixel, the first-1 direction and the second-1 direction may cross each other, and the first-2 direction and the second-2 direction may cross each other.

In an embodiment, the upper surface of each of the first-1 pixel electrode and the first-2 pixel electrode includes an inclined surface which is inclined with respect to the substrate and connects the first-1 valley and the first-1 peak to each other and the first-2 valley and the first-2 peak to each other.

In an embodiment, an angle of the inclined surface with respect to the substrate may be about 1° to about 45°.

In an embodiment, a protruded height of the inclined surface may be about 126 nanometers (nm) to about 260 nm.

In an embodiment, the display panel may further include a first color filter disposed over the first-1 pixel electrode and overlapping the first-1 pixel electrode, and a second color filter disposed over the first-2 pixel electrode and overlapping the first-2 pixel electrode.

In an embodiment, the display panel may further include a scattering layer interposed between the first-1 pixel electrode and the first color filter, and between the first-2 pixel electrode and the second color filter, or disposed on the first color filter and the second color filter, the scattering layer including a plurality of scattering particles.

In an embodiment, the display panel may further include an emission layer disposed on the first-1 pixel electrode, and a common electrode disposed on the emission layer.

In an embodiment of the disclosure, a display panel is provided, the display panel including a substrate, and a plurality of first pixel electrodes which are disposed on the substrate and each of which has an upper surface including a first valley and a first peak, each extending in a first direction, where the first direction is random in the plurality of first pixel electrodes.

In an embodiment, the display panel may further include a plurality of second pixel electrodes which are disposed on the substrate and each of which has an upper surface including a second valley and a second peak, each extending in a second direction, where the second direction may be random in the plurality of second pixel electrodes.

In an embodiment of the disclosure, an electronic apparatus is provided, the electronic apparatus including a processor, and a display panel controlled by the processor, where the display panel includes a substrate, a first-1 pixel electrode disposed on the substrate and having an upper surface including a first-1 valley and a first-1 peak, each extending in a first-1 direction, and a first-2 pixel electrode disposed on the substrate and having an upper surface including a first-2 valley and a first-2 peak, each extending in a first-2 direction crossing the first-1 direction.

In an embodiment, the first-1 pixel electrode and the first-2 pixel electrode may be arranged in sub-pixels emitting light of a same first color.

In an embodiment, the electronic apparatus may further include a second-1 pixel electrode disposed on the substrate and including an upper surface including a second-1 valley and a second-1 peak, each extending in a second-1 direction, and a second-2 pixel electrode disposed on the substrate and including an upper surface including a second-2 valley and a second-2 peak, each extending in a second-2 direction crossing the second-1 direction.

In an embodiment, the first-1 pixel electrode and the first-2 pixel electrode may be arranged in sub-pixels emitting light of a same first color, and the second-1 pixel electrode and the second-2 pixel electrode may be arranged in sub-pixels emitting light of a same second color.

In an embodiment, the upper surface of each of the first-1 pixel electrode and the first-2 pixel electrode may include an inclined surface which is inclined with respect to the substrate and connects the first-1 valley and the first-1 peak to each other and the first-2 valley and the first-2 peak to each other.

In an embodiment, an angle of the inclined surface with respect to the substrate may be about 1° to about 45°.

Other features and advantages will be apparent from predetermined descriptions, claims, and drawings to carry out the disclosure below.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic block diagram of an embodiment of an electronic apparatus of the disclosure;

FIG. 2 is a schematic view of embodiments of electronic apparatuses of the disclosure;

FIG. 3 is a schematic view showing embodiments of a case where electronic apparatuses of the disclosure are wearable electronic apparatuses;

FIG. 4 is a schematic view showing embodiments of a case where electronic apparatuses of the disclosure are vehicle electronic apparatuses;

FIG. 5 is a schematic plan view of an embodiment of a display module including a display panel of the disclosure;

FIG. 6 is a schematic side view of the display module of FIG. 5;

FIG. 7 is a schematic cross-sectional view taken along line A-A′ of the display panel included in the display module of FIG. 5;

FIG. 8 is a schematic enlarged conceptual view of a region B of FIG. 7;

FIG. 9 is a schematic conceptual view of external light viewed by users in a display panel according to a comparative example;

FIG. 10 is a schematic conceptual view of external light viewed by users in a display panel according to another comparative example;

FIG. 11 is a schematic conceptual view of an embodiment of pixel electrodes in a display panel of the disclosure;

FIG. 12 is a schematic conceptual view of an embodiment of pixel electrodes in a display panel of the disclosure; and

FIG. 13 is a schematic conceptual view of an embodiment of external light viewed by users in a display panel of the disclosure.

### DETAILED DESCRIPTION

As the disclosure allows for various changes and numerous embodiments, illustrative embodiments will be illustrated in the drawings and described in the detailed description. Effects and features of the disclosure, and methods for achieving them will be clarified with reference to embodiments described below with reference to the drawings. However, the disclosure is not limited to embodiments described below and may be implemented in various forms.

Hereinafter, embodiments of the disclosure will be described with reference to the accompanying drawings, where, like or corresponding elements are given like reference numerals when describing with reference to the drawings, and a repeated description thereof is omitted.

In embodiments below, when various elements such as a layer, a region, a plate, or the like are disposed “on” another element, not only the elements may be disposed “directly on” the other element, but another element may be disposed therebetween. In addition, for convenience of description, in the drawings, the sizes of elements may be exaggerated or reduced. As an example, the size and thickness of each element shown in the drawings are arbitrarily represented for convenience of description, and thus, the disclosure is not necessarily limited thereto.

In an embodiment below, an x axis, a y axis and a z axis are not limited to three axes of the rectangular coordinate system, and may be interpreted in a broader sense including the same. For example, the x axis, y axis, and z axis may be perpendicular to one another, or may represent different directions that are not perpendicular to one another.

In embodiments below, such terms as first and second are not used in a limited meaning and are used for the purpose of distinguishing one element from another.

The singular forms “a,” “an,” and “the” as used herein are intended to include the plural forms as well unless the context clearly indicates otherwise.

In embodiments below, the terms “comprise,” or “include” as used herein specify the presence of stated features or elements but do not preclude the addition of one or more other features or elements.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the specification, “A and/or B” means A or B, or A and B. In addition, “at least one of A and B” means A or B, or A and B.

In embodiments below, when a layer, region, or element is referred to as being connected, it includes not only a case where the layer, region, or element is directly connected, but also a case where the layer, region, or element is indirectly connected with another layer, region, or element disposed therebetween. For example, in the present specification, when a layer, region, or element is referred to as being electrically connected, it represents a case where the layer, region, or element is directly electrically connected and/or a case where the layer, region, or element is indirectly electrically connected with another layer, region, or element disposed therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

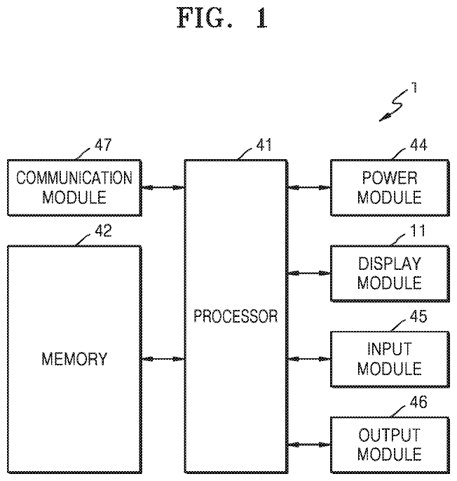

FIG. 1 is a schematic block diagram of an embodiment of an electronic apparatus 1 of the disclosure. The electronic apparatus 1 in the illustrated embodiment may be a display device, or may further include a module or the like having another additional function other than a display module 11.

As shown in FIG. 1, the electronic apparatus 1 in the illustrated embodiment may include the display module 11, a processor 41, a memory 42, a power module 44, an input module 45, an output module 46, and a communication module 47.

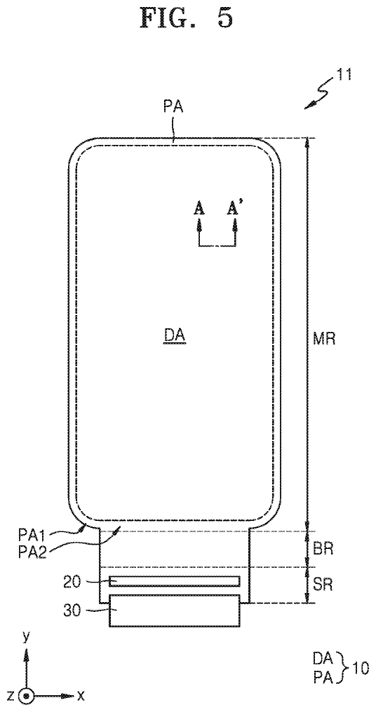

The display module 11 may include a display panel 10 (refer to FIG. 5) as described below. In an embodiment, the display module 11 may include the display panel 10 and a data driver 20 (refer to FIG. 5) disposed (e.g., mounted) thereon, or the like. The display panel 10 is described below.

The processor 41 may control most of elements of the electronic apparatus 1. In an embodiment, the processor 41 may output digital video data to the display module 11 such that the display module 11 displays images, and may receive input data from the input module 45 to allow a function corresponding to the relevant data to be performed by the electronic apparatus 1. The processor 41 may include at least one of a central processing unit (“CPU”), an application processor (“AP”), a graphic processing unit (“GPU”), a communication processor (“CP”), an image signal processor (“ISP”), and a controller.

When desired, the processor 41 may be divided into two or more portions in a functional or structural viewpoint. In an embodiment, the processor 41 may include a main processor in the form of a first driving chip including a central processing unit, and an auxiliary processor in the form of a second driving chip, which is a portion of the display module 11. The auxiliary processor in the form of the second driving chip may include a controller receiving image signals from the main processor and processing image signals to match interface specifications of the display panel 10 included in the display module 11.

The memory 42 may include at least one of a non-volatile memory and a volatile memory. The memory 42 may store data information desired for operations of the processor 41 or the display module 11. When the processor 41 executes an application stored in the memory 42, data signals for images and/or an input control signal may be transferred to the display module 11, and the display module 11 may process provided signals and output image information.

The power module 44 may include a power supply module such as a power adapter or a battery unit, and a power converting module converting power supplied by the power supply module and generating power desired for operations of the electronic apparatus (also referred to as an electronic device) 1. Power conversion by the power converting module may include DC-DC conversion, AC-DC conversion, and DC-AC conversion. However, the disclosure is not limited thereto.

The input module 45 may provide input information to the processor 41 and/or the display module 11. The input module 45 may include not only a physical button, a keyboard, and a microphone, but also various kinds of sensor modules. In embodiments, the sensor module may include a touch sensor, a pressure sensor, a distance sensor, a position sensor, a digitizer, a motion recognition sensor, a camera sensor, a light reception sensor, a photoelectric conversion sensor, and/or a temperature sensor. In addition, the sensor module may include biometric sensors such as a blood pressure sensor, a blood sugar sensor, an electrocardiogram sensor, and/or a heart rate sensor.

The output module 46 may receive information other than images received from the processor 41 and may provide the information to a user. The output module 46 may include a sound module, a haptic module, and/or a light-emitting module, for example. In addition, the output module 46 may include a unique functional module of the electronic apparatus 1 such as a cooling module of a refrigerator.

For reference, the display module 11 may be also in charge of an output function. In an embodiment, the display panel 10 included in the display module 11 may display (output) information processed by the electronic apparatus 1. In an embodiment, the display panel 10 may display execution screen information of an application driven by the electronic apparatus 1, a user interface (“UI”), or graphic UI (“GUI”) information corresponding to the execution screen information. The display panel 10 may include a display layer displaying images and a touchscreen layer sensing a user's touch input. Accordingly, the display panel 10 may serve as a portion of the input module 45 that provides an input interface between the electronic apparatus 1 and a user, and simultaneously, serve as a portion of the output module 46 that provides an output interface between the electronic apparatus 1 and a user.

The communication module 47 is a module responsible for transmission/reception of information between the electronic device 1 and an external apparatus, and may include a receiver and a transmitter. The communication module 47 may include various kinds of wireless communication modules such as a mobile communication module, a broadcasting reception module, a wireless Internet module, a short range communication module, a Wi-Fi module, and/or a Bluetooth® module, or various kinds of wired communication modules.

The electronic apparatus 1 shown in FIG. 1 is just an example. In an embodiment, a display device not having a communication function may not include the communication module 47. In addition, in the case where the electronic apparatus 1 includes a display device, at least one of elements of the electronic apparatus 1 may be included in the display device. In addition, some of individual modules functionally included in one module may be included in the display device, and other some may be included in the electronic apparatus 1 separately from the display device. In an embodiment, the display device may include the display module 11, and the processor 41, the memory 42, and the power module 44 may be elements of the electronic apparatus 1, not the display device. In an alternative embodiment, the display device may include the display module 11 and the power module 44, and the power module 44 may supply power to the elements such as the processor 41 and the memory 42 of the electronic apparatus 1. However, various modifications may be made.

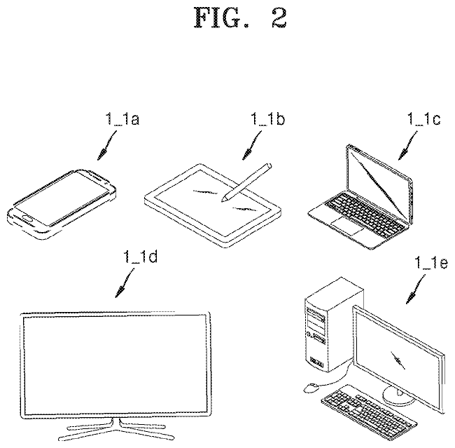

FIG. 2 is a schematic view of embodiments of the electronic apparatus 1 of the disclosure. FIG. 2 shows, in an embodiment of the electronic apparatus 1, a smartphone 1_1a, a tablet personal computer 1_1b, a laptop 1_1c, and a television (“TV”) 1_1d, and a desk monitor 1_1e.

The smartphone 1_1a may include not only the processor 41, the memory 42, the power module 44, and the display module 11, but also the input module 45 such as a touch sensor, and the communication module 47. The smartphone 1_1a may process information received through the communication module 47 or other input modules and display the information through the display module 11.

Similar to the smartphone 1_1a, the tablet personal computer 1_1b, the laptop 1_1c, the TV 1_1d, and/or the desk monitor 1_1e may include the display module 11 and the input module 45 and may also include the communication module 47 depending on a case.

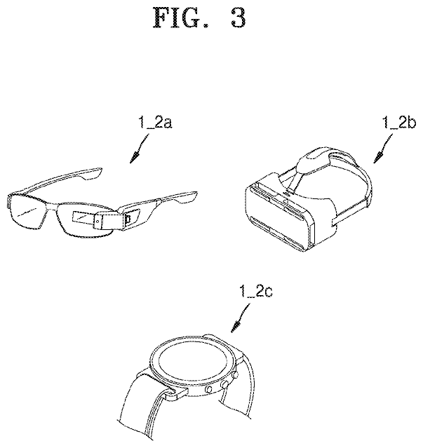

FIG. 3 is a schematic view showing embodiments of a case where the electronic apparatus 1 of the disclosure is a wearable electronic apparatus. FIG. 3 shows, in an embodiment of the electronic apparatus 1, a smart glasses 1_2a, a head mount display 1_2b, and a smartwatch 1_2c.

The smart glasses 1_2a and the head mount display 1_2b may include the display module 11 displaying images and a reflector reflecting a display surface displaying the images and providing the images to a user's eyes. A user may experience virtual reality or augmented reality using the electronic apparatus 1.

The smartwatch 1_2c may include a biometric sensor as the input module 45 and provide, through the display module 11, a user with bio information recognized through the biometric sensor.

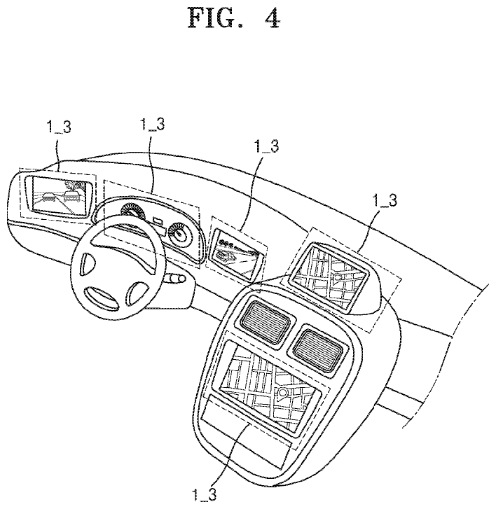

FIG. 4 is a schematic view showing embodiments of a case where the electronic apparatus 1 of the disclosure is a vehicle electronic device 1_3. As shown in FIG. 4, the vehicle electronic device 1_3 may be included in an instrument board, a center facia or the like of an automobile, or may be a center information display (“CID”) disposed on a dashboard of an automobile or a room mirror display replacing a side mirror.

However, the electronic apparatus 1 according to the disclosure is not limited thereto. In an embodiment, the electronic apparatus 1 of the disclosure may include not only devices centered on displays such as billboards, electronic boards, and/or game consoles, but also various home appliances that display information through the display module 11, such as a refrigerator, a washing machine, a dryer, an air conditioner, and/or a robot vacuum cleaner. In addition, in the case where the display module 11 has a function of transmitting light, the electronic apparatus 1 may be a smart window or a transparent display device displaying a background and display images together. However, the electronic apparatus 1 according to the disclosure is not limited thereto. As long as the electronic apparatus 1 includes the display panel 10 described below, any electronic apparatus may fall within the scope of the disclosure.

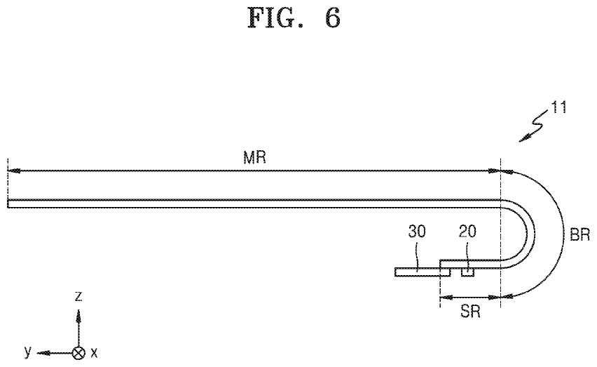

FIG. 5 is a schematic plan view of an embodiment of the display module 11 including the display panel 10 of the disclosure, and FIG. 6 is a schematic side view of the display module 11 of FIG. 5. The display module 11 included in the electronic apparatus 1 may include the display panel 10 as shown in FIGS. 5 and 6. This is also applicable to embodiments below and modifications thereof.

The display panel 10 may be shown to have a roughly quadrangular shape, e.g., rectangular shape in a plan view. In an embodiment, as shown in FIG. 5, the display panel 10 may have a roughly quadrangular shape, e.g., rectangular shape having short sides in a first direction (an x axis direction) and long sides in a second direction (a y axis direction) in an xy-plane. In this case, an edge where a short side in the first direction (the x axis direction) meets a long side in the second direction (the y axis direction) may form a right angle or have a round shape with a preset curvature. In a plan view, the shape of the display panel 10 is not limited to a rectangle, and may include other polygonal, elliptical, or irregular shapes.

The display panel 10 may include a display area DA and a peripheral area PA outside the display area DA. The display area DA is a region in which images are displayed, and a plurality of pixels may be disposed in the display area DA. The display area DA may have various shapes, e.g., circular shapes, elliptical shapes, polygonal shapes, or shapes of predetermined drawing figures. It is shown in FIG. 5 that the display area DA has a roughly quadrangular shape, e.g., rectangular shape having round corners.

The peripheral area PA may be disposed outside the display area DA. The peripheral area PA may include a first peripheral area PA1 and a second peripheral area PA2, the first peripheral area PA1 is disposed to surround at least a portion of the display area DA, and the second peripheral area PA2 is disposed at the lower end of the display area DA to extend in the first direction (the x axis direction). That is, the second peripheral area PA2 may be disposed at the lower end in the second direction (the y axis direction) below the display area DA. The width of the second peripheral area PA2 in the first direction (the x axis direction) may be less than the width of the display area DA. At least a portion of the second peripheral area PA2 may be easy to bend through this structure.

A planar shape of the display panel 10 shown in FIG. 5 may be substantially equal to the shape of a substrate 100 included in the display panel 10. When the display panel 10 includes the display area DA and the peripheral area PA outside the display area DA, it may represent the substrate 100 includes the display area DA and the peripheral area PA outside the display area DA. Hereinafter, for convenience, description is made on the assumption that the substrate 100 includes the display area DA and the peripheral area PA.

The display panel 10 may include a main region MR, a bent region BR outside the main region MR, and a sub-region SR apart from the main region MR with the bent region BR therebetween. The main region MR may be disposed on one side of the bent region BR, and the sub-region SR may be disposed on an opposite side of the bent region BR. As shown in FIG. 6, the display panel 10 may be bent in the bent region BR, and when viewed from a third direction (e.g., a z axis direction), at least portion of the sub-region SR may overlap the main region MR.

Although it is shown in FIG. 6 that the display panel 10 is bent, the disclosure is not limited thereto. In an embodiment, the display panel 10 may be a foldable display panel, and in this case, the display panel 10 may be bent inside the display area DA around a bending axis crossing the display area DA. When desired, the display panel 10 may not be bent. The sub-region SR may be a non-display area.

As described above, the display panel 10 may be a rigid display panel that has rigidity and thus is not easily bent, or a flexible display panel that is flexible and thus is easily bendable, foldable, or rollable. In an embodiment, the display panel 10 may include a foldable display panel that is foldable and non-foldable, a curved display panel that has a curved display surface, a bent display panel in which a region except a display surface is bent, a rollable display panel that is rollable and unrollable, and a stretchable display panel that is stretchable.

The display module 11 including the display panel 10 may include a data driver 20 disposed (e.g., mounted) in the sub-region SR of the display panel 10. The data driver 20 may be disposed on the display panel 10 in the form of an integrated circuit (“IC”). In an embodiment, the data driver 20 may be a data driving integrated circuit generating data signals. The data driver 20 may be the auxiliary processor in the form of the second driving chip as described above and may be a portion of the processor 41.

A display circuit board 30 may be attached to the end of the sub-region SR of the display panel 10. That is, when desired, the display module 11 may include the display circuit board 30. The display circuit board 30 may be electrically connected to the data driver 20 or the like through a pad of the sub-region SR of the display panel 10.

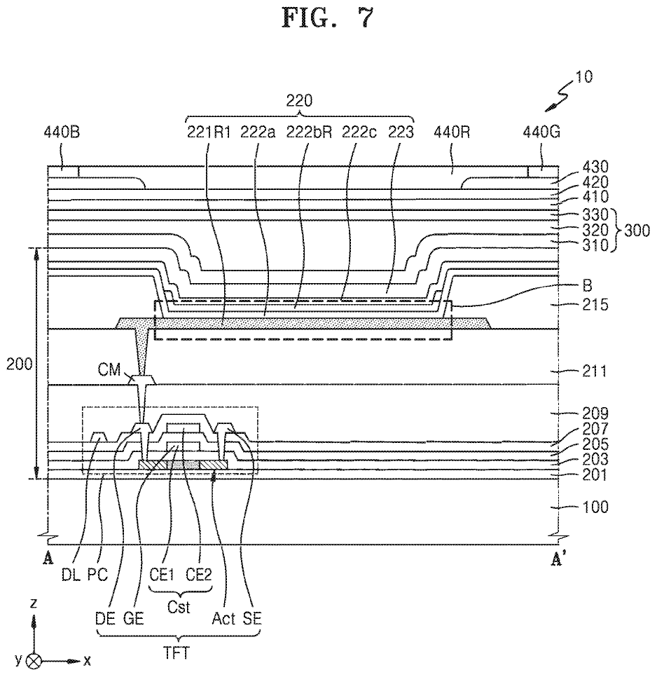

FIG. 7 is a schematic cross-sectional view taken along line A-A′ of the display panel 10 included in the display module 11 of FIG. 5. Referring to FIG. 7, the display panel 10 may include the substrate 100. Various elements forming the display panel 10 may be disposed on the substrate 100. In an embodiment, a display layer 200, a thin-film encapsulation layer 300, a touchscreen layer 410, a scattering layer 420, a light-blocking layer 430, and/or color filter layers 440R, 440G, and 440B may be disposed on the substrate 100.

The substrate 100 may include glass, ceramic, metal, or polymer resin. The substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers including the above-described polymer resin, and an inorganic material layer disposed therebetween. In an alternative embodiment, the substrate 100 may have a structure in which a layer including the polymer resin and an inorganic material layer are alternately stacked. The inorganic material layer may include silicon oxide, silicon nitride or silicon oxynitride, and may have a single-layered structure or a multi-layered structure, for example. The inorganic material layer may serve as a barrier layer preventing penetration of an external foreign substance.

The display layer 200 may include a plurality of pixels. The display layer 200 may include a display element 220 disposed for each pixel, a pixel circuit disposed for each pixel, and insulating layers. The pixel circuit may include a thin-film transistor TFT and a storage capacitor Cst. The display element 220 may include an organic light-emitting diode (“OLED”), for example.

The thin-film encapsulation layer 300 may cover the display layer 200. The thin-film encapsulation layer 300 may include at least one inorganic encapsulation layer and at least one organic encapsulation layer. The thin-film encapsulation layer 300 may prevent or reduce impurities such as moistures from the outside from penetrating the display elements.

The touchscreen layer 410 may generate data for sensing a user's touch input. The data is transferred to the main processor of the electronic apparatus 1, and the main processor may calculate touch coordinates at which a touch input occurs by analyzing the transferred data.

The light-blocking layer 430 and/or the color filter layers 440R, 440G, and 440B may reduce external light reflection. During a process of reducing external light reflection, the scattering layer 420 may reduce the occurrence of deterioration in image quality viewed to users.

Hereinafter, the display layer 200, the thin-film encapsulation layer 300, the touchscreen layer 410, the scattering layer 420, the light-blocking layer 430, and/or the color filter layers 440R, 440G, and 440B are specifically described.

A buffer layer 201 may be disposed on the substrate 100, and the buffer layer 201 is for preventing impurities from penetrating a semiconductor layer Act of the thin-film transistor TFT. The buffer layer 201 may include an inorganic insulating material such as silicon nitride, silicon oxynitride, and/or silicon oxide, and include a single-layered structure or a multi-layered structure.

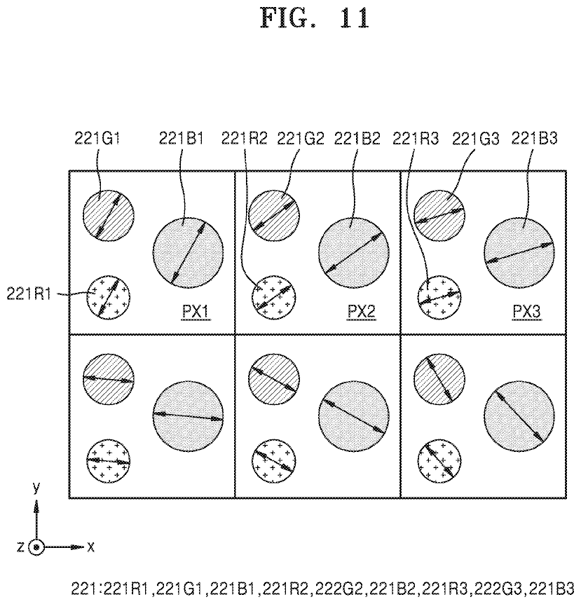

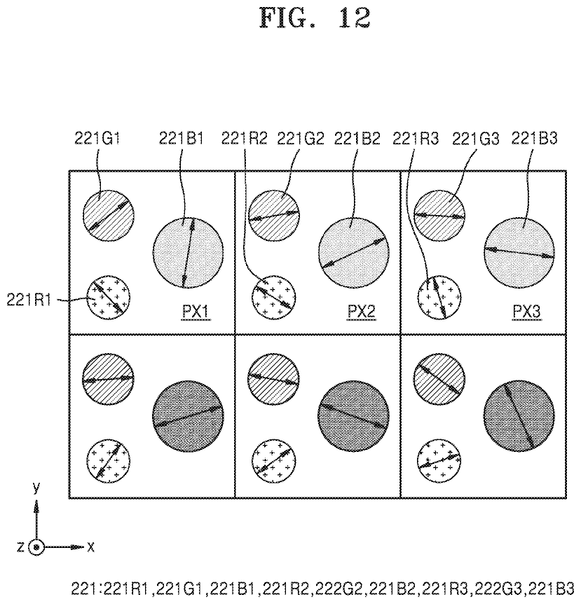

A pixel circuit PC may be disposed on the buffer layer 201. The pixel circuit PC may include the thin-film transistor TFT and the storage capacitor Cst. The thin-film transistor TFT may include the semiconductor layer Act, a gate electrode GE, a source electrode SE, and/or a drain electrode DE. The thin-film transistor TFT shown in FIG. 7 may be a driving transistor. When an emission control transistor or the like are disposed between the driving transistor and the OLED, in this case, unlike FIG. 7, the thin-film transistor TFT, which is the driving transistor, may not be connected to a pixel electrode 221 (refer to FIGS. 11 and 12) of the OLED through a contact metal layer CM and may be electrically connected to an emission control transistor (not shown), and the emission control transistor may be electrically connected to the pixel electrode 221 of the OLED. When desired, the thin-film transistor TFT shown in FIG. 7 may be regarded as the emission control transistor. Hereinafter, for convenience, a structure in which the thin-film transistor TFT of FIG. 7 is connected to the pixel electrode 221 of the OLED through the contact metal layer CM is described.

A data line DL of the pixel circuit PC may be electrically connected to a switching transistor included in the pixel circuit PC although not shown in FIG. 7.

The semiconductor layer Act may include polycrystalline silicon. In an alternative embodiment, the semiconductor layer Act may include amorphous silicon, an oxide semiconductor, or an organic semiconductor. The gate electrode GE may include a low-resistance metal material. In an embodiment, the gate electrode GE may include conductive materials including molybdenum (Mo), aluminum (Al), copper (Cu), and/or titanium (Ti), or the like and have a multi-layered structure or a single-layered structure. In an embodiment, the gate electrode GE may have a three-layered structure of a molybdenum layer, an aluminum layer, and a molybdenum layer (Mo/Al/Mo).

A gate insulating layer 203 between the semiconductor layer Act and the gate electrode GE may include an inorganic insulating material including silicon oxide, silicon nitride, silicon oxynitride, aluminum oxide, titanium oxide, tantalum oxide, and/or hafnium oxide or the like. The gate insulating layer 203 may have a single-layered structure or a multi-layered structure.

The source electrode SE and the drain electrode DE may be disposed in the same layer as the data line DL and may include the same material as a material of the data line DL. The source electrode SE, the drain electrode DE, and the data line DL may include a material having a relatively high conductivity. The source electrode SE and the drain electrode DE may include conductive materials including molybdenum (Mo), aluminum (Al), copper (Cu), titanium (Ti), or the like and have a multi-layered structure or a single-layered structure. In an embodiment, the source electrode SE, the drain electrode DE, and the data line DL may have a multi-layered structure of a titanium layer, an aluminum layer, and a titanium layer (Ti/Al/Ti).

Although it is shown in FIG. 7 that the thin-film transistor TFT includes both the source electrode SE and the drain electrode DE, the disclosure is not limited thereto. In an embodiment, a drain region of the semiconductor layer Act of the thin-film transistor TFT may be integrally formed (or unitary) with a source region of a semiconductor layer of another thin-film transistor. In this case, the thin-film transistor TFT may not have the drain electrode DE, and a remaining (the other) thin-film transistor may not have a source electrode. In this case, it may be shown in a circuit diagram that a drain of the thin-film transistor TFT is connected to a source of another thin-film transistor.

In an embodiment, when a drain of the driving transistor is connected to a source of the emission control transistor, the driving transistor may not have a drain electrode, the emission control transistor may not have a source electrode, and a drain region of a semiconductor layer of the driving transistor may be integrally formed (or unitary) with a source region of the emission control transistor. Similarly, when a source of the driving transistor is connected to a drain of an operation control transistor, the driving transistor may not have a source electrode, the operation control transistor may not have a drain electrode, and a source region of a semiconductor layer of the driving transistor may be integrally formed (or unitary) with a drain region of the operation control transistor. Accordingly, the driving transistor may consequently not have both a source electrode and a drain electrode.

The storage capacitor Cst may include a lower electrode CE1 and an upper electrode CE2 overlapping each other with a first inter-insulating layer 205 therebetween. The storage capacitor Cst may overlap the thin-film transistor TFT. It is shown in FIG. 7 that the gate electrode GE of the thin-film transistor TFT serves as the lower electrode CE1 of the storage capacitor Cst. However, the disclosure is not limited thereto, and the storage capacitor Cst may not overlap the thin-film transistor TFT. The storage capacitor Cst may be covered by a second inter-insulating layer 207. The upper electrode CE2 of the storage capacitor Cst may include conductive materials including molybdenum (Mo), aluminum (Al), copper (Cu), and/or titanium (Ti), or the like and have a multi-layered structure or a single-layered structure.

The first inter-insulating layer 205 and the second inter-insulating layer 207 may each include an inorganic insulating material including silicon oxide, silicon nitride, silicon oxynitride, aluminum oxide, titanium oxide, tantalum oxide, and/or hafnium oxide or the like. The first inter-insulating layer 205 and the second inter-insulating layer 207 may have a single-layered structure or a multi-layered structure.

The pixel circuit PC including the thin-film transistor TFT and the storage capacitor Cst may be covered by a first organic insulating layer 209.

The pixel circuit PC may be electrically connected to the pixel electrode 221. In an embodiment, as shown in FIG. 7, the contact metal layer CM may be disposed between the thin-film transistor TFT and the pixel electrode 221. The contact metal layer CM may be connected to the thin-film transistor TFT through a contact hole defined in the first organic insulating layer 209, and the pixel electrode 221 may be connected to the contact metal layer CM through a contact hole defined in a second organic insulating layer 211 disposed on the first organic insulating layer 209 to cover the contact metal layer CM or the like. The contact metal layer CM may include conductive materials including molybdenum (Mo), aluminum (AI), copper (Cu), and/or titanium (Ti), or the like and have a multi-layered structure or a single-layered structure. In an embodiment, the contact metal layer CM may have a multi-layered structure of a titanium layer, an aluminum layer, and a titanium layer (Ti/Al/Ti).

The first organic insulating layer 209 and the second organic insulating layer 211 may include an organic insulating material such as acryl, polystyrene (“PS”), polymethylmethacrylate (“PMMA”), benzocyclobutene (“BCB”), polyimide, or hexamethyldisiloxane (“HMDSO”). In an embodiment, the first organic insulating layer 209 and the second organic insulating layer 211 may each include polyimide. The first organic insulating layer 209 and/or the second organic insulating layer 211 may have a roughly flat upper surface. That is, the second organic insulating layer 211 may be a planarization layer.

The display element 220, which is a light-emitting element, may be disposed on the second organic insulating layer 211, which is a planarization layer. For convenience, FIG. 7 shows the display element 220 capable of emitting red light. The display element 220 capable of emitting red light may include a first-1 pixel electrode 221R1, a first functional layer 222a, a first emission layer 222bR, a second functional layer 222c, and/or a common electrode 223.

The first-1 pixel electrode 221R1 may be disposed on the second organic insulating layer 211. The first-1 pixel electrode 221R1 may be a (semi) light-transmissive electrode or a reflective electrode. In an embodiment, the first-1 pixel electrode 221R1 may include a reflective layer and a transparent or semi-transparent electrode layer on the reflective layer, and the reflective layer may include Ag, Mg, Al, Pt, Pd, Au, Ni, Nd, Ir, Cr, or combination thereof. The transparent or semi-transparent electrode layer may include at least one of indium tin oxide (“ITO”), indium zinc oxide (“IZO”), zinc oxide (ZnOX: ZnO or ZnO₂₎, indium oxide (In₂O₃), indium gallium oxide (“IGO”), or aluminum zinc oxide (“AZO”). In an embodiment, the first-1 pixel electrode 221R1 may have a three-layered structure of ITO/Ag/ITO.

The first-1 pixel electrode 221R1 may be connected to the contact metal layer CM under the second organic insulating layer 211 through a contact hole defined in the second organic insulating layer 211, and thus be electrically connected to the thin-film transistor TFT or the like. In addition, the upper surface of the first-1 pixel electrode 221R1 may not be flat such that users view high-quality images even when external light of relatively high brightness is incident to the display panel 10 and the electronic apparatus 1 including the display panel 10. A detailed structure of the first-1 pixel electrode 221R1 is described below in detail.

A pixel-defining layer 215 may be disposed on the second organic insulating layer 211. The pixel-defining layer 215 may prevent arcs or the like from occurring at the edge of the first-1 pixel electrode 221R1 by covering the edge of the first-1 pixel electrode 221R1 and increasing a distance between the first-1 pixel electrode 221R1 and the common electrode 223 over the first-1 pixel electrode 221R1. That is, the pixel-defining layer 215 may expose the central portion of the first-1 pixel electrode 221R1 by defining an opening. The pixel-defining layer 215 may include an organic insulating material such as polyimide, an acrylic resin, benzocyclobutene, a phenolic resin, or the like and be formed by spin coating or the like. In an alternative embodiment, the pixel-defining layer 215 may include an inorganic insulating material such as silicon nitride (SiNx), silicon oxynitride (SiON), or silicon oxide (SiOx).

An intermediate layer disposed between the first-1 pixel electrode 221R1 and the common electrode 223 may include the first emission layer 222bR. The intermediate layer may include the first functional layer 222a disposed between the first emission layer 222bR and the first-1 pixel electrode 221R1, or include the second functional layer 222c between the first emission layer 222bR and the common electrode 223. The first emission layer 222bR may include a polymer organic material or a low-molecular weight organic material emitting light having a preset color. The first emission layer 222bR shown in FIG. 7 may emit red light, for example.

The first functional layer 222a may include a single layer or a multi-layer. In an embodiment, in the case where the first functional layer 222a includes a polymer material, the first functional layer 222a may include a hole transport layer (“HTL”), which has a single-layered structure, and may include polyethylene dihydroxythiophene (poly-(3,4)-ethylene-dihydroxy thiophene (“PEDOT”)) or polyaniline (polyaniline “PANI”). In the case where the first functional layer 222a includes a low-molecular weight material, the first functional layer 222a may include a hole injection layer (“HIL”) and an HTL.

The second functional layer 222c may include an electron transport layer (“ETL”) and/or an electron injection layer (“EIL”).

The intermediate layer may be modified in various ways. In an embodiment, the intermediate layer may include a first stack, a second stack, and a charge generation layer between the first stack and the second stack, while the first stack includes the first emission layer 222bR, the first functional layer 222a, and the second functional layer 222c, and the second stack includes the first emission layer 222bR, the first functional layer 222a, and the second functional layer 222c. The charge generation layer may include a negative charge generation layer and a positive charge generation layer. A light-emission efficiency of a tandem type light-emitting diode (“LED”) including the plurality of first emission layers 222bR, may be enhanced even more by the negative charge generation layer and the positive charge generation layer.

The negative charge generation layer may be an n-type charge generation layer. The negative charge generation layer may supply electrons. The negative charge generation layer may include hosts and dopants. The host may include an organic material. The dopant may include a metal material. The positive charge generation layer may be a p-type charge generation layer. The positive charge generation layer may supply holes. The positive charge generation layer may include hosts and dopants. The host may include an organic material. The dopant may include a metal material.

As shown in FIG. 7, the first emission layer 222bR may be patterned to correspond to the first-1 pixel electrode 221R1 and may have an isolated shape. Unlike the first emission layer 222bR, the first functional layer 222a and/or the second functional layer 222c may be an integral body over a plurality of pixel electrodes. However, various modifications may be made.

An emission layer emitting light of a different color may be disposed in a different sub-pixel. In an embodiment, a second emission layer may be disposed on a second-1 pixel electrode 221G1 (refer to FIG. 11), and a third emission layer may be disposed on a third-1 pixel electrode 221B1 (refer to FIG. 11). Even in this case, the first functional layer 222a and the second functional layer 222c may be integral bodies over a plurality of sub-pixels and/or a plurality of pixels.

The common electrode 223 disposed on the intermediate layer may be a light-transmissive electrode or a semi-light-transmissive electrode. In an embodiment, the common electrode 223 may include a metal thin film with a relatively small work function including Li, Ca, Al, Ag, Mg or any combinations thereof (e.g., LiF). In addition, the common electrode 223 may further include a transparent conductive oxide (“TCO”) layer such as ITO, indium zinc oxide (“IZO”), ZnO, ZnO₂, or In₂O₃ disposed on the metal thin film.

The common electrode 223 may be integrally formed (or unitary) over the entirety of the surface of the display area DA to cover the display area DA and be disposed on the intermediate layer and the pixel-defining layer 215. That is, the common electrode 223 may be integrally formed (or unitary) to correspond to a plurality of OLEDs. The plurality of OLEDs may share the common electrode 223. A stack structure of the pixel electrode 221, the intermediate layer, and the common electrode 223 may correspond to the OLED, which is the display element 220.

A capping layer (not shown) may be disposed on the common electrode 223. The capping layer may include lithium fluoride (LiF), for example. The capping layer may be omitted.

The display element 220 such as the OLED may be covered by the thin-film encapsulation layer 300. When the capping layer is present, the thin-film encapsulation layer 300 may be disposed on the capping layer. The thin-film encapsulation layer 300 may include at least one organic encapsulation layer and at least one inorganic encapsulation layer. It is shown in FIG. 7 that the thin-film encapsulation layer 300 includes first and second inorganic encapsulation layers 310 and 330 and an organic encapsulation layer 320 therebetween. The number of organic encapsulation layers, the number of inorganic encapsulation layers, and a stacking order may be changed.

The first and second inorganic encapsulation layers 310 and 330 may include at least one inorganic material among aluminum oxide, titanium oxide, tantalum oxide, hafnium oxide, zinc oxide, silicon oxide, silicon nitride, and silicon oxynitride. Each of the first and second inorganic encapsulation layers 310 and 330 may have a single-layered structure or a multi-layered structure. The organic encapsulation layer 320 may include a polymer-based material. The polymer-based material may include an acryl-based resin such as polymethylmethacrylate or poly acrylic acid, an epoxy-based resin, polyimide, and/or polyethylene. In an embodiment, the organic encapsulation layer 320 may include acrylate.

The first inorganic encapsulation layer 310 and the second inorganic encapsulation layer 330 may include different materials from each other. In an embodiment, the first inorganic encapsulation layer 310 may include silicon oxynitride, and the second inorganic encapsulation layer 330 may include silicon nitride.

The first inorganic encapsulation layer 310 may have a curved portion along the shape of the common electrode 223. The organic encapsulation layer 320 may have a roughly flat upper surface, and accordingly, the second inorganic encapsulation layer 330 may also have a roughly flat shape.

The touchscreen layer 410 may sense a user's touch input by at least one of various touch methods such as a resistance layer method, a capacitance method or the like. In an embodiment, in the case where the touchscreen layer 410 of the display panel 10 senses a user's touch input by a capacitance method, a touch sensor driver may determine whether a user touches the touchscreen layer by applying driving signals to driving electrodes among touch electrodes, and sensing voltages between the driving electrodes and sensing electrodes through the sensing electrodes among the touch electrodes. The touch sensor driver may transfer sensor data to the main processor of the electronic apparatus 1 according to sensed voltages, and the main processor may calculate a touch coordinate at which a touch input occurs by analyzing the sensor data.

The light-blocking layer 430 and/or the color filter layers 440R, 440G, and 440B may reduce external light reflection. In an embodiment, the first color filter layer 440R overlapping the first-1 pixel electrode 221R1 may mainly pass red light, the second color filter layer 440G overlapping the second-1 pixel electrode 221G1 may mainly pass green light, and the third color filter layer 440B overlapping the third-1 pixel electrode 221B1 may mainly pass blue light. Accordingly, in an embodiment, in case of external light incident to the first color filter layer 440R, only red light among external light passes through the first color filter layer 440R, is reflected by the first-1 pixel electrode 221R1, and may pass through the first color filter layer 440R to progress to the outside. Accordingly, only about one-third (⅓) of external light incident to the first color filter layer 440R may be viewed to users. This is also true for the second color filter layer 440G and/or the third color filter layer 440B.

As described above, the pixel-defining layer 215 may expose the central portion of the first-1 pixel electrode 221R1 by defining an opening. The first color filter layer 440R may overlap the opening of the pixel-defining layer 215 exposing the central portion of the first-1 pixel electrode 221R1. As shown in FIG. 7, the area of the first color filter layer 440R may be greater than the area of a portion of the first-1 pixel electrode 221R1 that is not covered by the pixel-defining layer 215. This is applicable to the second color filter layer 440G and the second-1 pixel electrode 221G1, and applicable to the third color filter layer 440B and the third-1 pixel electrode 221B1.

The light-blocking layer 430 may be a black matrix, for example. The light-blocking layer 430 may be interposed between the first color filter layer 440R and the second color filter layer 440G or disposed to correspond to the boundary between the first color filter layer 440R and the second color filter layer 440G, be interposed between the first color filter layer 440R and the third color filter layer 440B or disposed to correspond to the boundary between the first color filter layer 440R and the third color filter layer 440B, and be interposed between the third color filter layer 440B and the second color filter layer 440G or disposed to correspond to the boundary between the third color filter layer 440B and the second color filter layer 440G.

The scattering layer 420, which may be interposed between pixel electrodes (such as the first-1 pixel electrode 221R1, the second-1 pixel electrode 221G1, the third-1 pixel electrode 221B1, and the pixel electrodes described below) and the light-blocking layer 430 and/or the color filter layers 440R, 440G, and 440B, e.g., disposed under the light-blocking layer 430 and/or the color filter layers 440R, 440G, and 440B, may be a layer including a plurality of scattering particles therein. That is, the scattering layer 420 may have a structure in which scattering particles such as nano particles are dispersed in a polymer layer. The scattering particles may be nano particles including, e.g., silicon oxide. The polymer layer may include PMMA, for example. Unlike FIG. 7, the scattering layer 420 may be disposed on the light-blocking layer 430 and/or the color filter layers 440R, 440G, and 440B.

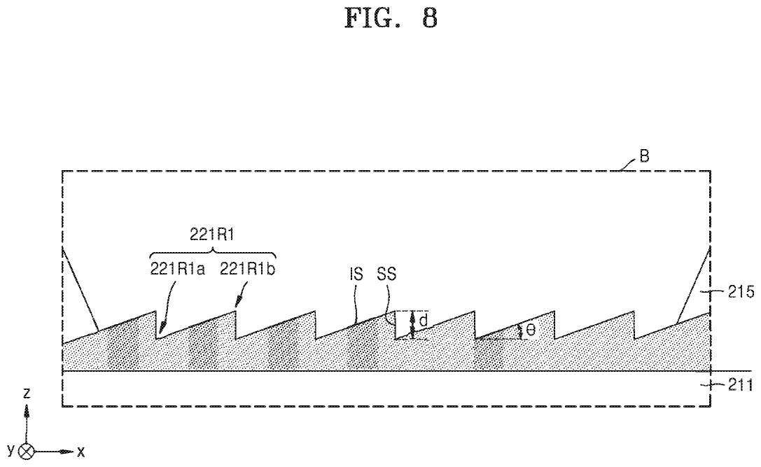

FIG. 8 is a schematic enlarged view of a region B of FIG. 7. As shown in FIG. 8, the first-1 pixel electrode 221R1 may have an upper surface including a valley (also referred to as a first-1 valley) 221R1a and a peak (also referred to as a first-1 peak) 221R1b. The valley 221R1a and the peak 221R1b may have a shape extending in a first-1 direction. It is shown in FIG. 8 as an example that the valley 221R1a and the peak 221R1b each extends in a y axis direction. For reference, although the first-1 pixel electrode 221R1 may have an approximately flat lower surface as shown in FIG. 8, the disclosure is not limited thereto. In an embodiment, the lower surface of the first-1 pixel electrode 221R1 may have a slightly curved surface due to wirings or conductive layers disposed therebelow. This is true for remaining (the other) pixel electrodes.

Although it is shown in FIG. 8 that the upper surface of the first-1 pixel electrode 221R1 includes a plurality of valleys 221R1a and a plurality of peaks 221R1b, the disclosure is not limited thereto. In an embodiment, the upper surface of the first-1 pixel electrode 221R1 may include one valley 221R1a and two peaks 221R1b. However, various modifications may be made. Hereinafter, for convenience, the case where the upper surface of the first-1 pixel electrode 221R1 includes the plurality of valleys 221R1a and the plurality of peaks 221R1b is described.

The upper surface of the first-1 pixel electrode 221R1 may include an inclined surface IS connecting the valley 221R1a and the peak 221R1b to each other. In an embodiment, the upper surface of the first-1 pixel electrode 221R1 may include a plurality of inclined surfaces IS. The inclined surface IS may have a shape inclined with respect to the substrate 100 (e.g., the upper surface of the substrate 100). The upper surface of the first-1 pixel electrode 221R1 may also include a side surface SS approximately perpendicular to the substrate 100. The inclined surface IS may meet the side surface SS at an end in a direction away from the substrate 100. An edge (the peak 221R1b) formed where the inclined surface IS and the side surface SS meet may form a protrusion of the first-1 pixel electrode 221R1. A distance d from the valley 221R1a to the edge (the peak 221R1b) formed where the inclined surface IS and the side surface SS meet may be a protruded height of the inclined surface IS.

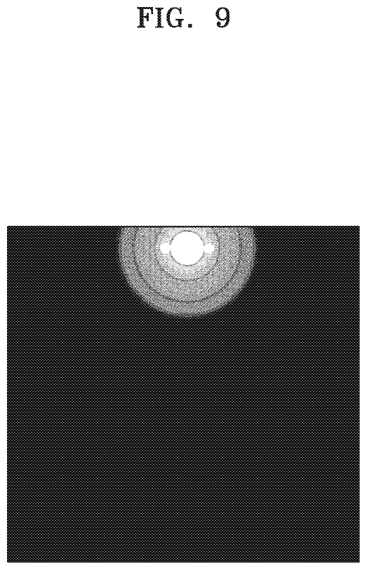

FIG. 9 is a schematic conceptual view of external light viewed to users in a display panel and an electronic apparatus including the same according to a comparative example. In the case where there is a light source having relatively high brightness outside the display panel and the electronic apparatus including the same, light from the external light source is incident to the display panel and the electronic apparatus including the same, and then, reflected and viewed to users. In this case, as shown in FIG. 9, users view circular reflected light corresponding to the external light, and concentric reflected light appearing around it due to a diffraction effect. Such reflected light deteriorates the user's ability to view the image, resulting in deterioration in the quality of the image displayed by the display panel and the electronic apparatus including the display panel.

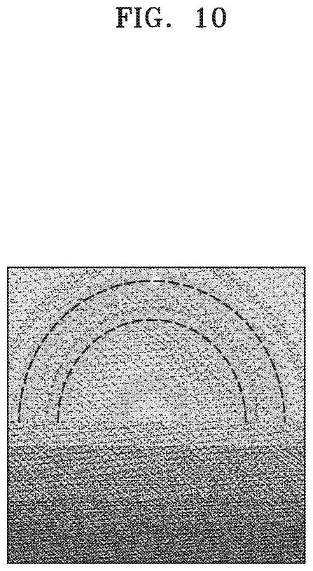

As described above, in the case where the display panel 10 and the electronic apparatus 1 including the same include the scattering layer 420, the scattering layer 420 may alleviate the diffraction phenomenon that appears as shown in FIG. 9. In this case, external light may appear as shown in FIG. 10, which is a schematic conceptual view of externa light viewed to users in a display panel according to a comparative example. As shown in FIG. 10, the generation of concentric reflected light that appears around circular reflected light corresponding to an external light source may be reduced. However, in this case, users may view reflected light like a rainbow color due to scattering in a portion indicated by the dotted line in FIG. 10. Although the brightness of the reflected light due to such scattering is less than the brightness of the reflected light due to diffraction as shown in FIG. 9, it may still deteriorate the user's ability to view images.

In the display panel 10 and the electronic apparatus 1 including the same in the illustrated embodiment, the display panel 10 and the electronic apparatus 1 including the same, capable of increasing the user's ability to view images and displaying high-quality images by adjusting an extension direction of the valleys and the peaks in the pixel electrodes described above, may be implemented.

FIG. 11 is a schematic conceptual view of an embodiment of pixel electrodes in the display panel 10 of the disclosure. As shown in FIG. 11, the display panel 10 and the electronic apparatus 1 including the same in the illustrated embodiment may include a first-2 pixel electrode 221R2 in addition to the first-1 pixel electrode 221R1 described above. The first-2 pixel electrode 221R2 may have an equal or similar shape to that of the first-1 pixel electrode 221R1. However, a direction in which the valley and the peak of the first-2 pixel electrode 221R2 extend may be different from a direction in which the valley and the peak of the first-1 pixel electrode 221R1 extend.

As described above, the first-1 pixel electrode 221R1 may have an upper surface including the plurality of valleys 221R1a and the plurality of peaks 221R1b. The plurality of valleys 221R1a and the plurality of peaks 221R1b may have a shape extending in the first-1 direction. In FIG. 11, the first-1 direction is indicated by an arrow within the first-1 pixel electrode 221R1.

The first-2 pixel electrode 221R2 may also have an upper surface including a plurality of valleys (also referred to as first-2 valleys) and a plurality of peaks (also referred to as first-2 peaks). The plurality of valleys and the plurality of peaks of the first-2 pixel electrode 221R2 may extend in a first-2 direction. In FIG. 11, the first-2 direction is indicated by an arrow within the first-2 pixel electrode 221R2. As shown in FIG. 11, the first-2 direction may cross the first-1 direction. That is, the first-2 direction may be different from the first-1 direction.

For reference, like the first-1 pixel electrode 221R1, the upper surface of the first-2 pixel electrode 221R2 may include one valley and two peaks. However, various modifications may be made. Hereinafter, for convenience, the case where the upper surface of the first-2 pixel electrode 221R2 includes a plurality of valleys and a plurality of peaks is described.

When all pixel electrodes include a plurality of valleys and a plurality of peaks extending in the first-1 direction as the first-1 pixel electrode 221R1, reflected light due to scattering indicated by dotted lines in FIG. 10 may be viewed to users. When all the pixel electrodes include a plurality of valleys and a plurality of peaks extending in the same direction and the direction is a predetermined direction different from the first-1 direction, reflected light due to scattering similar to the reflected light indicated by dotted line in FIG. 10 may be viewed to users, but the shape of the reflected light due to scattering may be different from the shape of the reflected light shown in FIG. 10. In an embodiment, because, in FIG. 10, the reflected light due to scattering has a shape similar to arcs with open bottoms, all the pixel electrodes include a plurality of valleys and a plurality of peaks extending in the same direction, and the direction is a predetermined direction different from the first-1 direction. However, the reflected light due to scattering may have a shape similar to arcs with open right sides, for example.

As described above, the first-2 direction in which the plurality of valleys and the plurality of peaks of the first-2 pixel electrodes 221R2 extend is different from the first-1 direction in which the plurality of valleys and the plurality of peaks of the first-1 pixel electrodes 221R1 extend. Accordingly, the influence of the first-1 pixel electrode 221R1 on the direction of reflected light due to scattering is different from the influence of the first-2 pixel electrode 221R2 on the direction of reflected light due to scattering. Accordingly, in the display panel 10 and the electronic apparatus 1 including the same, it is possible to prevent or minimize the formation of reflected light due to scattering of a predetermined shape and being recognized by users.

As shown in FIG. 11, the first-1 direction in the first-1 pixel electrode 221R1 belonging to a first pixel PX1 and the first-2 direction in the first-2 pixel electrode 221R2 belonging to a second pixel PX2 are not limited to being different, but a first-3 direction in a first-3 pixel electrode 221R3 belonging to another pixel, e.g., a third pixel PX3, may also be different. Here, the first-1 pixel electrode 221R1, the first-2 pixel electrode 221R2, and the first-3 pixel electrode 221R3 may emit light of a first color, e.g., red light. That is, the first-1 pixel electrode 221R1, the first-2 pixel electrode 221R2, and the first-3 pixel electrode 221R3 may be arranged in sub-pixels emitting light of the same first color. Furthermore, assuming that the first-1 pixel electrode 221R1, the first-2 pixel electrode 221R2, and the first-3 pixel electrode 221R3 are first pixel electrodes, and a direction in which the valleys (also referred to as first valleys) and the peaks (also referred to as first peaks) extend in the first pixel electrodes is a first direction, the first direction may be random in the display panel 10 and the electronic apparatus 1 including the same.

The second-1 pixel electrode 221G1 included in the first pixel PX1 may include an upper surface including a valley (also referred to as a second-1 valley) and a peak (also referred to as a second-1 peak). The valleys and the peaks may have a shape extending in a second-1 direction. In FIG. 11, the second-1 direction is indicated by an arrow within the second-1 pixel electrode 221G1.

For reference, like the first-1 pixel electrode 221R1, the upper surface of the second-1 pixel electrode 221G1 may include a plurality of valleys and plurality of peaks. The upper surface of the second-1 pixel electrode 221G1 may include one valley and two peaks. However, various modifications may be made. Hereinafter, for convenience, the case where the upper surface of the second-1 pixel electrode 221G1 includes a plurality of valleys and a plurality of peaks is described.

The second-2 pixel electrode 221G2 included in the second pixel PX2 may include an upper surface including a plurality of valleys (also referred to as second-2 valleys) and a plurality of peaks (also referred to as second-2 peaks). The plurality of valleys and the plurality of peaks of the second-2 pixel electrode 221G2 may extend in a second-2 direction. In FIG. 11, the second-2 direction is indicated by an arrow within the second-2 pixel electrode 221G2. As shown in FIG. 11, the second-2 direction may cross the second-1 direction. That is, the second-2 direction may be different from the second-1 direction.

For reference, like the second-1 pixel electrode 221G1, the upper surface of the second-2 pixel electrode 221G2 may include one valley and two peaks. However, various modifications may be made. Hereinafter, for convenience, the case where the upper surface of the second-2 pixel electrode 221G2 includes a plurality of valleys and a plurality of peaks is described.

Through this structure, the influence of the second-1 pixel electrode 221G1 on the direction of reflected light due to scattering may be different from the influence of the second-2 pixel electrode 221G2 on the direction of reflected light due to scattering. Accordingly, in the display panel 10 and the electronic apparatus 1 including the same, it is possible to prevent or minimize the formation of reflected light due to scattering of a predetermined shape and being recognized by users.

As shown in FIG. 11, the second-1 direction in the second-1 pixel electrode 221G1 belonging to the first pixel PX1 and the second-2 direction in the second-2 pixel electrode 221G2 belonging to the second pixel PX2 are not limited to being different, but a second-3 direction in a second-3 pixel electrode 221G3 belonging to another pixel, e.g., the third pixel PX3, may also be different. Here, the second-1 pixel electrode 221G1, the second-2 pixel electrode 221G2, and the second-3 pixel electrode 221G3 may emit light of a second color, e.g., green light. That is, the second-1 pixel electrode 221G1, the second-2 pixel electrode 221G2, and the second-3 pixel electrode 221G3 may be arranged in sub-pixels emitting light of the same second color. Furthermore, assuming that the second-1 pixel electrode 221G1, the second-2 pixel electrode 221G2, and the second-3 pixel electrode 221G3 are second pixel electrodes, and a direction in which the valleys (also referred to as second valleys) and the peaks (also referred to as second peaks) extend in the second pixel electrodes is a second direction, the second direction may be random in the display panel 10 and the electronic apparatus 1 including the same.

The third-1 pixel electrode 221B1 included in the first pixel PX1 may include an upper surface including a valley and a peak. The valley and the peak may have a shape extending in a third-1 direction. In FIG. 11, the third-1 direction is indicated by an arrow within the third-1 pixel electrode 221B1.

For reference, like the first-1 pixel electrode 221R1, the upper surface of the third-1 pixel electrode 221B1 may include a plurality of valleys and plurality of peaks. The upper surface of the third-1 pixel electrode 221B1 may include one valley and two peaks. However, various modifications may be made. Hereinafter, for convenience, the case where the upper surface of the third-1 pixel electrode 221B1 includes a plurality of valleys and a plurality of peaks is described.

The third-2 pixel electrode 221B2 included in the second pixel PX2 may include an upper surface including a plurality of valleys and a plurality of peaks. The plurality of valleys and the plurality of peaks of the third-2 pixel electrode 221B2 may extend in a third-2 direction. In FIG. 11, the third-2 direction is indicated by an arrow within the third-2 pixel electrode 221B2. As shown in FIG. 11, the third-2 direction may cross the third-1 direction. That is, the third-2 direction may be different from the third-1 direction.

For reference, like the third-1 pixel electrode 221B1, the upper surface of the third-2 pixel electrode 221B2 may include one valley and two peaks. However, various modifications may be made. Hereinafter, for convenience, the case where the upper surface of the third-2 pixel electrode 221B2 includes a plurality of valleys and a plurality of peaks is described.

Through this structure, the influence of the third-1 pixel electrode 221B1 on the direction of reflected light due to scattering may be different from the influence of the third-2 pixel electrode 221B2 on the direction of reflected light due to scattering. Accordingly, in the display panel 10 and the electronic apparatus 1 including the same, it is possible to prevent or minimize the formation of reflected light due to scattering of a predetermined shape and being recognized by users.

As shown in FIG. 11, the third-1 direction in the third-1 pixel electrode 221B1 belonging to the first pixel PX1 and the third-2 direction in the third-2 pixel electrode 221B2 belonging to the second pixel PX2 are not limited to being different, but a third-3 direction in a third-3 pixel electrode 221B3 belonging to another pixel, e.g., the third pixel PX3, may also be different. Here, the third-1 pixel electrode 221B1, the third-2 pixel electrode 221B2, and the third-3 pixel electrode 221B3 may emit light of a third color, e.g., blue light. That is, the third-1 pixel electrode 221B1, the third-2 pixel electrode 221B2, and the third-3 pixel electrode 221B3 may be arranged in sub-pixels emitting light of the same third color. Furthermore, assuming that the third-1 pixel electrode 221B1, the third-2 pixel electrode 221B2, and the third-3 pixel electrode 221B3 are third pixel electrodes, and a direction in which the valleys and the peaks extend in the third pixel electrodes is a third direction, the third direction may be random in the display panel 10 and the electronic apparatus 1 including the same.

It is shown in FIG. 11 that the first-1 direction, the second-1 direction, and the third-1 direction are parallel to each other, the first-2 direction, the second-2 direction, and the third-2 direction are parallel to each other, and the first-3 direction, the second-3 direction, and the third-3 direction are parallel to each other. That is, within one pixel, directions in which the valleys and the peaks extend in the pixel electrodes are shown to be the same. However, the disclosure is not limited thereto.

FIG. 12 is a schematic conceptual view of an embodiment of pixel electrodes in the display panel 10 of the disclosure. As shown in FIG. 12, within the first pixel PX1, at least one of the first-1 direction, the second-1 direction, and the third-1 direction may be different. In an embodiment, all of the first-1 direction, the second-1 direction, and the third-1 direction may be different from each other to cross each other. Also within the second pixel PX2, at least one of the first-2 direction, the second-2 direction, and the third-2 direction may be different. In an embodiment, all of the first-2 direction, the second-2 direction, and the third-2 direction may be different from each other to cross each other. Also within the third pixel PX3, at least one of the first-3 direction, the second-3 direction, and the third-3 direction may be different. In an embodiment, all of the first-3 direction, the second-3 direction, and the third-3 direction may be different from each other to cross each other.

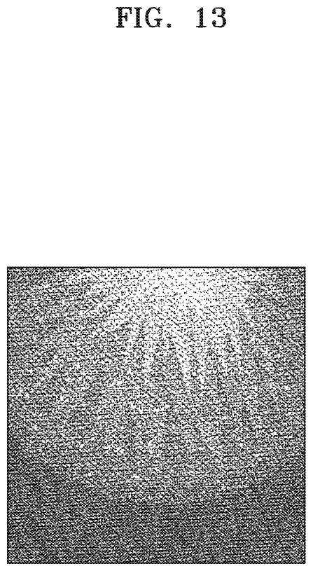

FIG. 13 is a schematic conceptual view of an embodiment of external light viewed to users in the display panel 10 of the disclosure. As shown in FIG. 13, in the display panel 10 and the electronic apparatus 1 including the same in the illustrated embodiment, even when there is a light source of relatively high brightness in the outside, generation of reflected light due to diffraction of light from the light source or reflected light due to scattering is prevented or minimized, and thus, users may view high-quality images.

As described above with reference to FIG. 8, the upper surface of the first-1 pixel electrode 221R1 may include the inclined surface IS inclined with respect to the substrate 100 (e.g., the upper surface of the substrate 100). An angle θ formed by this inclined surface IS with respect to the substrate 100 or the upper surface of the substrate 100 may be about 1° to about 45°. Because the angle θ is 1° or more, a plurality of peaks may be formed in one pixel electrode. When the angle θ exceeds 45°, light reflected by the pixel electrode and progressing to the outside after being generated from the emission layer may be directed in a lateral direction without being directed in the front direction of the display panel 10 and the electronic apparatus 1 including the same. Accordingly, the angle θ is preferably 45° or less.

As described above, the inclined surface IS may meet the side surface SS approximately perpendicular to the substrate 100 at an end in a direction away from the substrate 100. An edge formed where the inclined surface IS and the side surface SS may meet may form a protrusion of the first-1 pixel electrode 221R1. A distance d from the valley 221R1a to the edge formed where the inclined surface IS and the side surface SS meet may be a protruded height of the inclined surface IS. The distance d may be about 126 nanometers (nm) to about 260 nm. A phase @ of reflected light may be determined by the distance d using Equation 1 below.

$$ΔΦ = \frac{2 π}{λ} nd \qquad [ Equation 1 ]$$

Here, λ is the wavelength of incident light, and n is a refractive index. For a phase difference to be 2π, when the refractive index is 1.5, d is 126 nm with respect to a wavelength of 380 nm corresponding to blue light, d is 175 nm with respect to a wavelength of 560 nm corresponding to green light, and d is 260 nm with respect to a wavelength of 780 nm corresponding to red light. Accordingly, the distance d may be about 126 nm to about 260 nm.

Although, up to this point, the structure of the display panel 10 has been mainly described, the disclosure is not limited thereto. The electronic apparatus 1 including the display panel 10 also falls within the scope of the disclosure.

In an embodiment of the disclosure, a display panel capable of displaying high-quality images and an electronic apparatus including the same may be implemented. However, the scope of the disclosure is not limited by this effect.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display panel comprising:
a substrate;
a first-1 pixel electrode disposed on the substrate, the first-1 pixel electrode including:
an upper surface including a first-1 valley and a first-1 peak, each extending in a first-1 direction; and
a first-2 pixel electrode disposed on the substrate, the first-2 pixel electrode including:
an upper surface including a first-2 valley and a first-2 peak, each extending in a first-2 direction crossing the first-1 direction.

2. The display panel of claim 1, wherein the first-1 pixel electrode and the first-2 pixel electrode are arranged in sub-pixels emitting light of a same first color.

3. The display panel of claim 1, further comprising:
a second-1 pixel electrode disposed on the substrate and including an upper surface including a second-1 valley and a second-1 peak, each extending in a second-1 direction; and
a second-2 pixel electrode disposed on the substrate and including an upper surface including a second-2 valley and a second-2 peak, each extending in a second-2 direction crossing the second-1 direction.

4. The display panel of claim 3, wherein the first-1 pixel electrode and the first-2 pixel electrode are arranged in sub-pixels emitting light of a same first color, and the second-1 pixel electrode and the second-2 pixel electrode are arranged in sub-pixels emitting light of a same second color.

5. The display panel of claim 3, wherein the first-1 pixel electrode and the second-1 pixel electrode belong to a first pixel, the first-2 pixel electrode and the second-2 pixel electrode belong to a second pixel, the first-1 direction and the second-1 direction are parallel to each other, and the first-2 direction and the second-2 direction are parallel to each other.

6. The display panel of claim 3, wherein the first-1 pixel electrode and the second-1 pixel electrode belong to a first pixel, the first-2 pixel electrode and the second-2 pixel electrode belong to a second pixel, the first-1 direction and the second-1 direction cross each other, and the first-2 direction and the second-2 direction cross each other.

7. The display panel of claim 1, wherein the upper surface of each of the first-1 pixel electrode and the first-2 pixel electrode includes an inclined surface which is inclined with respect to the substrate and connects the first-1 valley and the first-1 peak to each other and the first-2 valley and the first-2 peak to each other.

8. The display panel of claim 7, wherein an angle of the inclined surface with respect to the substrate is about 1° to about 45°.

9. The display panel of claim 7, wherein a protruded height of the inclined surface is about 126 nanometers to about 260 nanometers.

10. The display panel of claim 1, further comprising:
a first color filter disposed over the first-1 pixel electrode and overlapping the first-1 pixel electrode; and
a second color filter disposed over the first-2 pixel electrode and overlapping the first-2 pixel electrode.

11. The display panel of claim 10, further comprising a scattering layer interposed between the first-1 pixel electrode and the first color filter and between the first-2 pixel electrode and the second color filter, or disposed on the first color filter and the second color filter, the scattering layer including a plurality of scattering particles.

12. The display panel of claim 1, further comprising an emission layer disposed on the first-1 pixel electrode, and a common electrode disposed on the emission layer.

13. A display panel comprising:
a substrate; and
a plurality of first pixel electrodes which are disposed on the substrate, each of the plurality of first pixel electrodes including:
an upper surface including a first valley and a first peak, each extending in a first direction,
wherein the first direction is random in the plurality of first pixel electrodes.

14. The display panel of claim 13, further comprising a plurality of second pixel electrodes which are disposed on the substrate and each of which has an upper surface including a second valley and a second peak, each extending in a second direction, wherein the second direction is random in the plurality of second pixel electrodes.

15. An electronic apparatus comprising:
a processor; and
a display panel controlled by the processor, the display panel including:
a substrate;
a first-1 pixel electrode disposed on the substrate, the first-1 pixel electrode including:
an upper surface including a first-1 valley and a first-1 peak, each extending in a first-1 direction; and
a first-2 pixel electrode disposed on the substrate, the first-2 pixel electrode including:
an upper surface including a first-2 valley and a first-2 peak, each extending in a first-2 direction crossing the first-1 direction.

16. The electronic apparatus of claim 15, wherein the first-1 pixel electrode and the first-2 pixel electrode are arranged in sub-pixels emitting light of a same first color.

17. The electronic apparatus of claim 15, further comprising:
a second-1 pixel electrode disposed on the substrate and including an upper surface including a second-1 valley and a second-1 peak, each extending in a second-1 direction; and
a second-2 pixel electrode disposed on the substrate and including an upper surface including a second-2 valley and a second-2 peak, each extending in a second-2 direction crossing the second-1 direction.

18. The electronic apparatus of claim 17, wherein the first-1 pixel electrode and the first-2 pixel electrode are arranged in sub-pixels emitting light of a same first color, and the second-1 pixel electrode and the second-2 pixel electrode are arranged in sub-pixels emitting light of a same second color.

19. The electronic apparatus of claim 15, wherein the upper surface of each of the first-1 pixel electrode and the first-2 pixel electrode includes an inclined surface which is inclined with respect to the substrate and connects the first-1 valley and the first-1 peak to each other and the first-2 valley and the first-2 peak to each other.

20. The electronic apparatus of claim 19, wherein an angle of the inclined surface with respect to the substrate is about 1° to about 45°.
